(19) United States
(12) Patent Application Publication
(10) Pub. No.: US 2019/0121230 A1
(43) Pub. Date: Apr. 25, 2019

(54) IMAGE PROCESSING CONVOLUTION ALGORITHM FOR DEFECT DETECTION

(71) Applicant: ASML HOLDING N.V., Veldhoven (NL)

(72) Inventor: Guobin OU, Westport, CT (US)

(21) Appl. No.: 16/092,591

(22) PCT Filed: Mar. 24, 2017
(86) PCT No.: PCT/EP2017/057035

§ 371 Date: Oct. 10, 2018

Related U.S. Application Data
(60) Provisional application No. 62/328,459, filed on Apr. 27, 2016.

(51) Int. Cl. G03F 1/84; G06T 5/20; G03F 7/20; G06K 9/00; G06T 7/00

(52) U.S. Cl. CPC G03F 1/84; G06T 5/20; G06T 7/001; G03F 7/7065; G06K 9/00671; G03F 7/70491

(57) ABSTRACT

A method including obtaining a first image of an object, generating a second image by convolving the first image with a filter kernel, wherein each pixel value of the second image is a weighted combination of a plurality of accumulation values associated with surrounding pixels of the first image, and determining, based on the second image, whether the object includes a defect.

### CROSS-REFERENCE TO RELATED APPLICATIONS

This application claims priority of U.S. Provisional Patent Application No. 62/328,459, which was filed on Apr. 27, 2016 and which is incorporated herein in its entirety by reference.

### FIELD

The present description relates to methods and apparatus for defect detection on, e.g., a patterning device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti parallel to this direction. It is also possible to transfer the pattern from the patterning device to the substrate by imprinting the pattern onto the substrate.

### SUMMARY

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

One or more defects, such as particles on, for example, a patterning device, may represent, or result in, production errors of a substrate in the patterning process. The defects or production errors may include thinning or necking (e.g., line thinning or necking), bridging or shorting, an opening or disconnect, pullback (e.g., line end pullback), etc. One or more of these defects or production errors be a yield-damaging fault.

Therefore, it is desirable to provide a technique to detect one or more defects, e.g., one or more particles on a patterning device, errors on a substrate, etc. When the one or more defects are detected, appropriate actions may be taken. For example, one or more defects can be removed from the patterning device, for example, by providing a flowing gas on the surface of the patterning device. As a further example, one or more compensations can be taken based on the detection of the one or more defects to reduce the effect of the one or more defects on the patterning process. As a result, production defects of a substrate may be reduced.

In an embodiment, there is provided a method comprising: obtaining a first image of an object; generating a second image by convolving the first image with a filter kernel, wherein each pixel value of the second image is a weighted combination of a plurality of accumulation values associated with surrounding pixels of the first image; and determining, based on the second image, whether the object includes a defect.

In an embodiment, there is provided a non-transitory computer program product comprising machine-readable instructions configured to cause a processor to cause performance of a method as described herein.

In an embodiment, there is provided a system comprising: a patterning device inspection tool configured to provide an image of a patterning device; and an image analysis engine comprising a non-transitory computer program product as described herein. In an embodiment, the system further comprises a lithographic apparatus comprising a support structure configured to hold the patterning device to modulate a radiation beam.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Embodiments will now be described, by way of example only, with reference to the accompanying drawings in which:

FIG. 1 schematically depicts an embodiment of a lithographic apparatus;

FIG. 2 schematically depicts an embodiment of a lithographic cell or cluster;

FIG. 3 is a flow diagram illustrating an example inspection process of a patterning device;

FIGS. 4A, 4B and 4C schematically depict an example of decomposing a kernel matrix to a combination of two child matrices;

FIGS. 5A, 5B and 5C schematically depict an example of decomposing a kernel matrix to a combination of two child matrices;

FIG. 6 schematically depicts an example method of calculating an accumulation value at a pixel;

FIG. 7 schematically depicts an example method of calculating an integration value between two pixels; and

FIG. 8 is a computer system which may implement embodiments of this disclosure.

### DETAILED DESCRIPTION

Before describing embodiments in detail, it is instructive to present an example environment in which embodiments may be implemented.

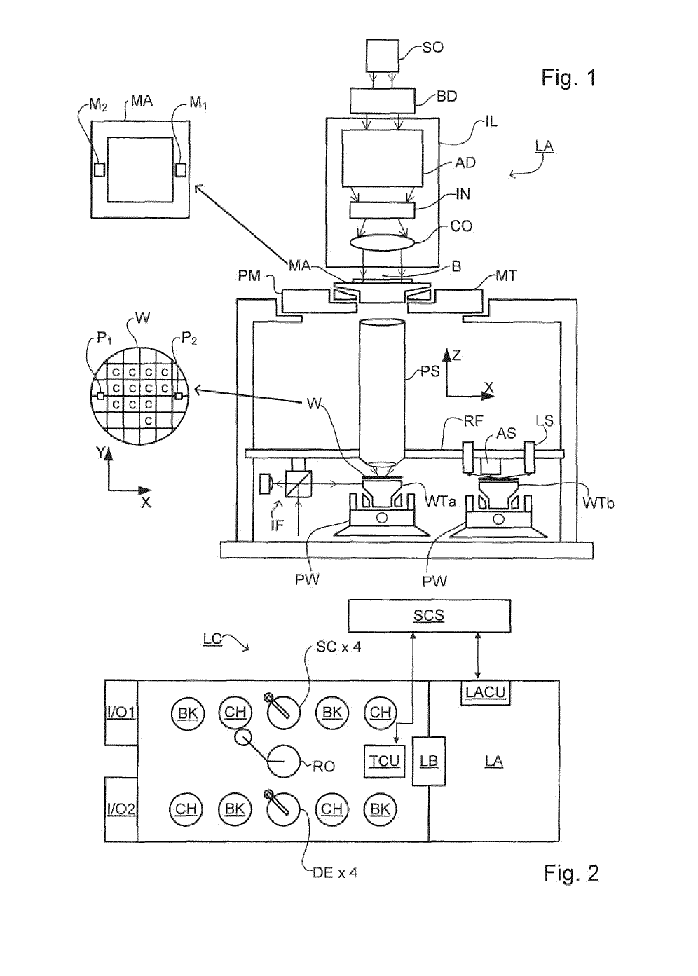

FIG. 1 schematically depicts a lithographic apparatus LA. The apparatus comprises:
an illumination system (illuminator) IL configured to condition a radiation beam B (e.g. DUV radiation or EUV radiation);
a support structure (e.g. a mask table) MT constructed to support a patterning device (e.g. a mask) MA and connected to a first positioner PM configured to accurately position the patterning device in accordance with certain parameters;
a substrate table (e.g. a wafer table) WTa constructed to hold a substrate (e.g. a resist-coated wafer) W and connected to a second positioner PW configured to accurately position the substrate in accordance with certain parameters; and
a projection system (e.g. a refractive or reflective projection system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The patterning device support structure holds the patterning device in a manner that depends on the orientation of the patterning device, the design of the lithographic apparatus, and other conditions, such as for example whether or not the patterning device is held in a vacuum environment. The patterning device support structure can use mechanical, vacuum, electrostatic or other clamping techniques to hold the patterning device. The patterning device support structure may be a frame or a table, for example, which may be fixed or movable as required. The patterning device support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more tables (e.g., two or more substrate table, two or more patterning device support structures, or a substrate table and metrology table). In such “multiple stage” machines the additional tables may be used in parallel, or preparatory steps may be carried out on one or more tables while one or more other tables are being used for pattern transfer.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross section.

The radiation beam B is incident on the patterning device (e.g., mask) MA, which is held on the patterning device support (e.g., mask table MT), and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan. In general, movement of the patterning device support (e.g., mask table) MT may be realized with the aid of a long-stroke module (coarse positioning) and a short-stroke module (fine positioning), which form part of the first positioner PM. Similarly, movement of the substrate table WTa may be realized using a long-stroke module and a short-stroke module, which form part of the second positioner PW. In the case of a stepper (as opposed to a scanner) the patterning device support (e.g., mask table) MT may be connected to a short-stroke actuator only, or may be fixed.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment markers may also be included within dies, in amongst the device features, in which case it is desirable that the markers be as small as possible and not require any different imaging or process conditions than adjacent features. The alignment system, which detects the alignment markers is described further below.

The depicted apparatus could be used in at least one of the following modes:
In step mode, the patterning device support (e.g., mask table) MT and the substrate table WTa are kept essentially stationary, while an entire pattern imparted to the radiation beam is projected onto a target portion C at one time (i.e., a single static exposure). The substrate table WTa is then shifted in the X and/or Y direction so that a different target portion C can be exposed. In step mode, the maximum size of the exposure field limits the size of the target portion C imaged in a single static exposure.
In scan mode, the patterning device support (e.g., mask table) MT and the substrate table WTa are scanned synchronously while a pattern imparted to the radiation beam is projected onto a target portion C (i.e., a single dynamic exposure). The velocity and direction of the substrate table WTa relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
In another mode, the patterning device support (e.g., mask table) MT is kept essentially stationary holding a programmable patterning device, and the substrate table WTa is moved or scanned while a pattern imparted to the radiation beam is projected onto a target portion C. In this mode, generally a pulsed radiation source is employed and the programmable patterning device is updated as required after each movement of the substrate table WTa or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

Lithographic apparatus LA is of a so-called dual stage type which has two tables WTa, WTb (e.g., two substrate tables) and two stations—a pattern transfer station and a measurement station—between which the tables can be exchanged. For example, while a substrate on one table is having a pattern transferred thereto at the pattern transfer station, another substrate can be loaded onto the other substrate table at the measurement station and various preparatory steps carried out. The preparatory steps may include mapping the surface control of the substrate using a level sensor LS and measuring the position of alignment markers on the substrate using an alignment sensor AS, both sensors being supported by a reference frame RF. If the position sensor IF is not capable of measuring the position of a table while it is at the measurement station as well as at the pattern transfer station, a second position sensor may be provided to enable the positions of the table to be tracked at both stations. As another example, while a substrate on one table has a pattern transferred thereto at the pattern transfer station, another table without a substrate waits at the measurement station (where optionally measurement activity may occur). This other table has one or more measurement devices and may optionally have other tools (e.g., cleaning apparatus). When the substrate has completed pattern transfer thereto, the table without a substrate moves to the pattern transfer station to perform, e.g., measurements and the table with the substrate moves to a location (e.g., the measurement station) where the substrate is unloaded and another substrate is load. These multi-table arrangements enable a substantial increase in the throughput of the apparatus.

As shown in FIG. 2, the lithographic apparatus LA may form part of a lithographic cell LC, also sometimes referred to as a lithocell or lithocluster, which also includes apparatus to perform one or more pre- and post-pattern transfer processes on a substrate. Conventionally these include one or more spin coaters SC to deposit a resist layer, one or more developers DE to develop exposed resist, one or more chill plates CH and one or more bake plates BK. A substrate handler, or robot, RO picks up a substrate from input/output ports I/O1, I/O2, moves it between the different process devices and delivers it to the loading bay LB of the lithographic apparatus. These devices, which are often collectively referred to as the track, are under the control of a track control unit TCU which is itself controlled by the supervisory control system SCS, which also controls the lithographic apparatus via lithographic control unit LACU. Thus, the different apparatus may be operated to maximize throughput and processing efficiency.

It is desirable to inspect a patterned substrate to measure one or more properties such as overlay error between subsequent layers, line thickness, critical dimension (CD), etc. If an error is detected, an adjustment may be made to, for example, patterning of one or more subsequent substrates. This may particularly useful, for example, if the inspection can be done soon and fast enough that another substrate of the same batch is still to be patterned. Also, an already patterned substrate may be stripped and reworked (to improve yield) or discarded, thereby avoiding performing patterning on a substrate that is known to be faulty. In a case where only some target portions of a substrate are faulty, further patterning may be performed only on those target portions which are good. Another possibility is to adapt a setting of a subsequent process step to compensate for the error, e.g. the time of a trim etch step can be adjusted to compensate for substrate-to-substrate CD variation resulting from a lithographic process step. As discussed further below, measurements may be used in the patterning process design (e.g., in designing the device design).

An inspection apparatus is used to determine one or more properties of a substrate, and in particular, how one or more properties of different substrates or different layers of the same substrate vary from layer to layer and/or across a substrate. The inspection apparatus may be integrated into the lithographic apparatus LA or the lithocell LC or may be a stand-alone device. To enable most rapid measurements, it is desirable that the inspection apparatus measure one or more properties in the resist layer immediately after patterning. In an embodiment, the measurement may be taken of a latent image in exposed resist. But, the latent image in the resist has a very low contrast—there is only a very small difference in refractive index between the part of the resist which has been exposed to radiation and that which has not. So, measurements may be taken after the post-exposure bake step (PEB) which is customarily the first step carried out on an exposed substrate and increases the contrast between exposed and unexposed parts of the resist. At this stage, the image in the resist may be referred to as semi-latent. Further, in an embodiment and commonly, measurements may be made of the developed resist image—at which point either the exposed or unexposed parts of the resist have been removed—or after a pattern transfer step such as etching. Measuring after etching limits the possibility for rework of a faulty substrate but may still provide useful information, e.g. for the purpose of process control.

As noted above, one or more defects, such as particles on a patterning device, may result in or represent yield loss of substrates in a patterning process. It is desirable to provide a defect detection process to automatically detect one or more defects so that appropriate actions may be taken to remove or compensate for the detected one or more defects. In an embodiment, the defect detection process is applied to determining defects of a patterning device (such as particles on the patterning device). As will be appreciated, the process and techniques described herein can be applied for other types of detection than determining defects of a patterning device. That is, the detection could be to detect something other than defects. Alternatively or additionally, that is, the detection could be to detect defects of something other than a patterning device (e.g., detecting defects on a substrate such as a semiconductor substrate).

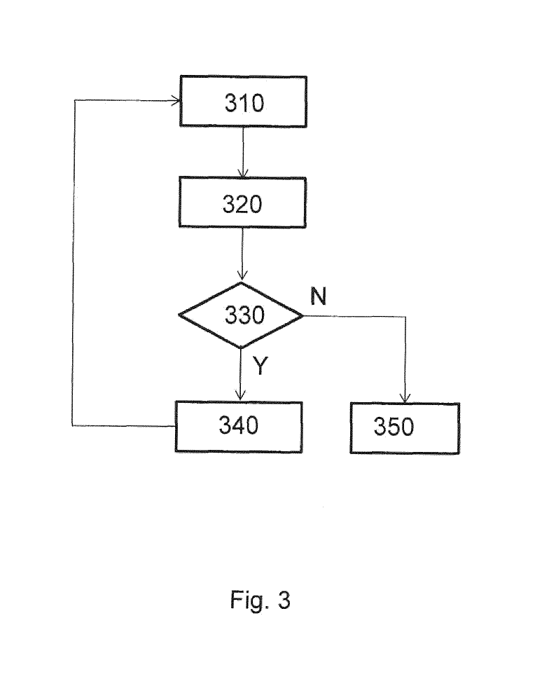

An example defect detection process is illustrated in FIG. 3. The process may be implemented by a software application installed in a computer system (which computer system can be part of an inspection apparatus, separate from an inspection apparatus (e.g., a stand-alone system or part of a different kind of apparatus), etc.).

At 310, one or more images of the object (e.g., a patterning device) under consideration are obtained, e.g., from an inspection tool. The one or more images of the object may include an image of the front side of the object, an image of the back side of the object, and/or both. In an embodiment, the images include a first image, D₁, of a substrate before a patterning process and a second image, D₂, of the substrate after the patterning process. In some examples, the first image may be of a bare substrate without any microscopic structures produced on the substrate. In some examples, the first image may be of a substrate that includes microscopic structures produced on the substrate previously. In the case of the first and second images of the substrate, the image used for further processing can be a difference image between the first image D₁ and the second image D₂, i.e., D₂−D₁. This is done so that the information prior to the patterning process is removed from the second image D₂. As a result, the difference image, D₂−D₁, reflects information only about the patterning process.

As used herein, images include a mathematical representation of a measured likeness of the object, e.g., a digital image representation. As used herein, images can include a derived mathematical representation of a likeness of the object, e.g., a digital representation of an expected likeness of the object.

There are various techniques for capturing the images of the object. Various tools for making such measurements are known including, but not limited to, scanning electron microscopes (SEMs), which are often used to measure critical dimension (CD). SEMs have high resolving power and are capable of resolving features of the order of 50 nm, 10 nm or less. SEM images of semiconductor devices are often used in the semiconductor fab to observe what is happening at the device level.

At 320, one or more new images are obtained by executing an algorithm to process each of the one or more images of the object (e.g., the measured one or more images, the difference image, etc.), e.g., by convolving each of the one or more images of the object with a high-pass filter kernel. This is done so that the calculated one or more new images exclude or suppress low spatial frequency components of the one or more images of the object and/or include or emphasize high spatial frequency components of the one or more images of the object. This takes advantage of a realization that defects, e.g., particles, have a high spatial frequency and other structures of the object, e.g., the device or functional patterns of a patterning device, have a low spatial frequency. Therefore, the defects, if any, on the object may be detected by determining whether the calculated one or more images include at least one high spatial frequency component. For example, when the calculated one or more images include one or more high spatial frequency components, it is determined that there is one or more defects (e.g., particles) on the object. Otherwise, it is determined that there is no defect (e.g., a particle) on the object.

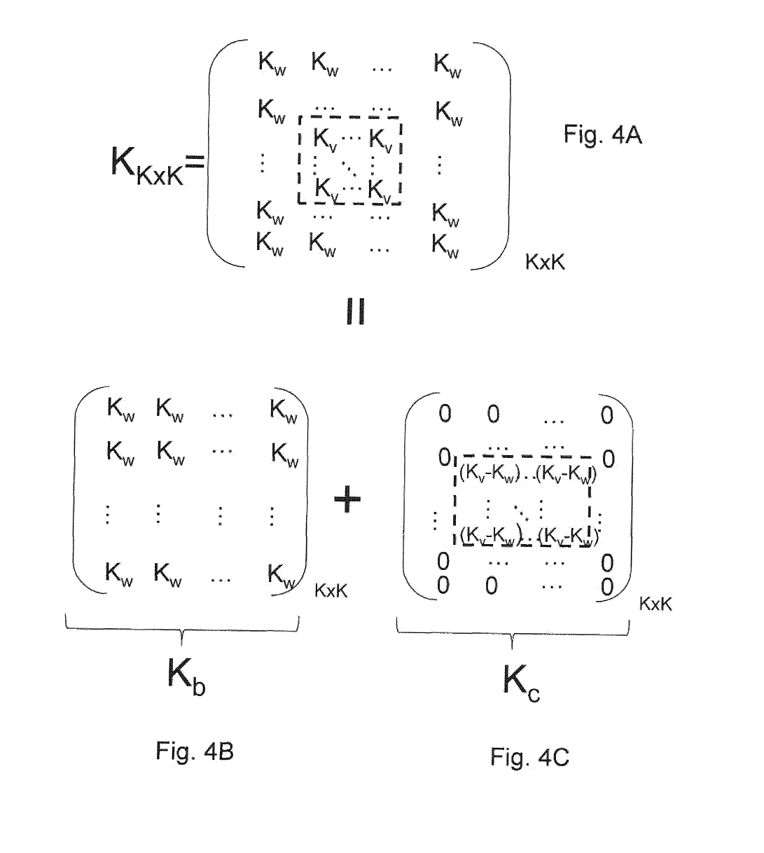

An example high-pass filter kernel may be a k×k matrix K_{k×k} as shown in FIG. 4A. The matrix K_{k×k} includes a k_{c}×k_{c} sub-matrix in the central portion, in which all the elements have a value of Kᵥ. All the other elements outside the sub-matrix in the matrix K_{k×k} have a value of k_{w}. In order to obtain the high-pass filtering characteristic, the value of kᵥ should be significantly larger than the value of k_{w}. For example, the value of kᵥ may be value larger than or equal to 20, e.g., 30, 40, 50, 60, 70, 80, 90, 100, 900, 1000, etc., and the value of k_{w} may be lower than or equal to 5, e.g., −1, −2, −3, 1, 2, etc. In an embodiment, the ratio between the value of kᵥ and the value of k_{w} is greater than or equal to 5, greater than or equal to 10, greater than or equal to 25, greater than or equal to 50, greater than or equal to 100, etc. Further, the matrix and sub-matrix need not be a square matrix. Thus, although the high-pass filter kernels in the examples herein are shown as square matrices, a more general high-pass filter kernel may be a kₓ×k_{y} rectangular matrix (where both kₓ and k_{y} are integers) with a rectangular sub-matrix, and accordingly, the equations herein would be appropriately modified to account for a generic rectangular matrix and/or sub-matrix.

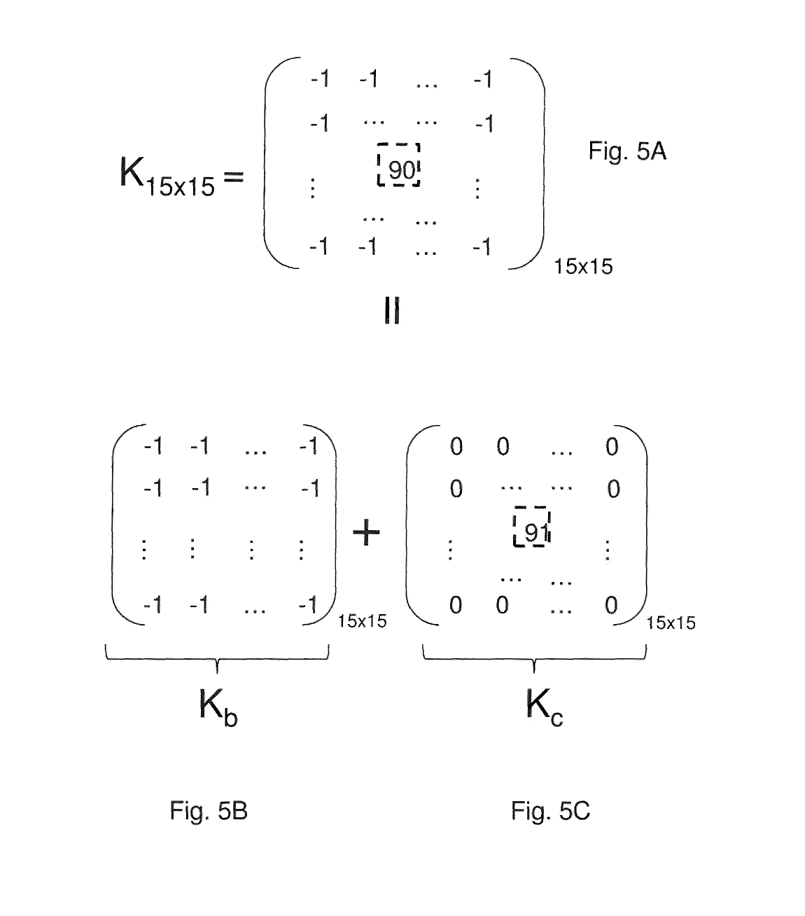

An example of the high-pass filter kernel, K₁₅ₓ₁₅, is shown in FIG. 5A. The high-pass filter kernel, K_{15×15}, has a single element of kᵥ=90 in the center, and all the other 224 elements have k_{w}=−1.

So, a calculated new image, D, may be expressed by:

D=S⊗K (1)

where S represents an image of the object (e.g., a measured image, a difference image difference image D₂−D₁, etc.), K represents the high-pass filter kernel as described above, and the operator ⊗ represents convolution. The image S is a matrix of M×N pixels, where M is the number of rows and N is the number of columns. Similarly, new image D will be a matrix of M×N pixels.

By definition of convolution, each pixel of the calculated image, e.g., D(x,y), may be expressed by:

$$D ( x , y ) = {\sum }_{{y}^{′} = - ⌊ \frac{{k}_{y}}{2} ⌋}^{⌊ \frac{{k}_{y}}{2} ⌋} {\sum }_{{x}^{′} = - ⌊ \frac{{k}_{x}}{2} ⌋}^{⌊ \frac{{k}_{x}}{2} ⌋} [ K ( ⌊ \frac{{k}_{x}}{2} ⌋ - {x}^{′} , ⌊ \frac{{k}_{y}}{2} ⌋ - {y}^{′} ) S ( x + {x}^{′} , y + {y}^{′} ) ] \qquad ( 2 )$$

where └ ┘ is a round down operator. So, when B is an integer, └B┘ is equal to B. Otherwise, └B┘ is equal to the closest integer that is smaller than B. For example, └7┘ is equal to 7, and └8.5┘ is equal to 8.

The calculation according to equation (2) is repeated M×N times to obtain all the M×N pixels of the image D. For example, a typical image may have 5120×5120 pixels, i.e., M=N=5120, with 10 bit pixel values. Therefore, there is a large amount of computations to obtain the image D. Thus, the computing speed to obtain image D can be slow. As a result, it may take a long time to compute and/or a large amount of computing power or resources to obtain the calculated image D.

A possible solution to shorten the computing time is based on a Fourier transform (FFT). Specifically, both the image of the object S, and the high-pass filter kernel K are first converted from the spatial domain to the spatial frequency domain using a conventional FFT algorithm. Then the product of the converted image of the object S and the converted high-pass filter kernel K in the spatial frequency domain is calculated. Then, the calculated image D is obtained by converting the calculated product back to the spatial domain using a conventional inverse FFT algorithm. Using this solution, the computing time may be significantly reduced but still relatively long. Therefore, it is desirable, for example, to provide a new algorithm to obtain the calculated image D with, e.g., a faster computing speed and/or using a lower amount of computation power or resources. Such a new algorithm will be described in greater detail with respect to FIGS. 4-7.

Returning to FIG. 3, at 330, once the calculated image D is determined, it is determined whether the calculated image D includes at least one high spatial frequency component. For example, each of the pixels can be evaluated against a threshold and those pixels that pass a threshold are indicative of a defect. Further thresholding can be applied, such as determining whether there are a sufficient number of adjacent pixels that pass the threshold. If there are one or more high spatial frequency components in image D, it is indicated that there is at least one defect on the object (e.g., a particle on the patterning device, a defect of a semiconductor substrate, etc.). As a result, the process proceeds to step 340. If not, it is indicated that no defect on the object is detected. As a result, the process ends at 350.

At 340, one or more appropriate actions may be taken to remove or compensate for the one or more determined defects of the object. For example, a software application (not shown) may instruct a cleaning tool to clean the object (e.g., patterning device) to remove particles by providing a flowing gas on a surface of the object.

In an embodiment, the process returns to step 310. Thus, an iterative process may be provided that continues until it is determined that no defect that crosses a certain threshold remains on the object.

An improved process for step 320 is explained in more detail below.

FIGS. 4A-4C schematically depict an example of decomposing a high-pass filter kernel matrix K_{k×k} to two child matrices K_{b} and K_{c}. As shown in FIG. 4A, the kernel matrix K_{k×k} includes a k_{c}×k_{c} sub-matrix in a central portion, in which all the elements have a value of Kᵥ. All the other elements outside the k_{c}×k_{c} sub-matrix in the matrix K_{k×k} have a value of k_{w}. As described above, in an embodiment, the value of Kᵥ is much greater than the value of k_{w}. As shown in FIGS. 4B and 4C, the kernel matrix K_{k×k} may be decomposed to a combination of two child matrices K_{b} and K_{c}. Specifically, as shown in FIG. 4B, K_{b} is a k×k matrix with the same elements, K_{w}, and, as shown in FIG. 4C, K_{c} is a k×k matrix with all the elements equal to zero except that each element of the central k_{c}×k_{c} sub-matrix is equal to (kᵥ-k_{w}).

FIGS. 5A-5C schematically depict a specific example of decomposing a high-pass filter kernel matrix to two child matrices. In this example, the high-pass filter kernel matrix K_{15×15} is a 15×15 matrix in which each element equals to −1 except the center element equals to 90. As shown, the kernel matrix K_{15×15} can be expressed by a combination of two child matrices, K_{b} and K_{c}. Specifically, as shown in FIG. 5B, K_{b} is a 15×15 matrix with each pixel equal to −1, and, as shown in FIG. 5C, K, is a 15×15 matrix with each element equal to 0 except that the center element equals to 91.

Now, by substituting the high-pass filter kernel matrix K_{k×k} in equation (1) with k_{b}+k_{c}, equation (1) becomes:

$$\begin{matrix}\begin{matrix}D = S ⊗ ( {K}_{b} + {K}_{c} ) \\ = S ⊗ {K}_{b} + S ⊗ {K}_{c} \\ = {k}_{w} S ⊗ U ( k , k ) + ( {k}_{v} - {k}_{w} ) S ⊗ U ( {k}_{c} , {k}_{c} )\end{matrix} & ( 3 )\end{matrix}$$

where U(k,k) is a uniform k×k matrix of is, and U(k_{c},k_{c}) is a uniform k_{c}×k_{c} matrix of is.

Combining equations (2) and (3), an arbitrary pixel of the calculated image D, e.g., D(x,y) may be therefore expressed by:

$$D ( x , y ) = {k}_{w} {\sum }_{{y}^{′} = - ⌊ \frac{k}{2} ⌋}^{⌊ \frac{k}{2} ⌋} {\sum }_{{x}^{′} = - ⌊ \frac{k}{2} ⌋}^{⌊ \frac{k}{2} ⌋} [ S ( x + {x}^{′} , y + {y}^{′} ) ] + ( {k}_{v} - {k}_{w} ) {\sum }_{{y}^{′} = - ⌊ \frac{{k}_{c}}{2} ⌋}^{⌊ \frac{{k}_{c}}{2} ⌋} {\sum }_{{x}^{′} = - ⌊ \frac{{k}_{c}}{2} ⌋}^{⌊ \frac{{k}_{c}}{2} ⌋} [ S ( x + {x}^{′} , y + {y}^{′} ) ] \qquad ( 4 )$$

where S(x,y) represents the pixel (x,y) of the image of the object.

Now, before further simplifying equation (4), an accumulation value at a pixel (x,y) of the image of the object can be defined as:

A(x,y)=Σ_{x′=0}^{x}Σ_{y′=0}^{y}S(x′,y′) (5)

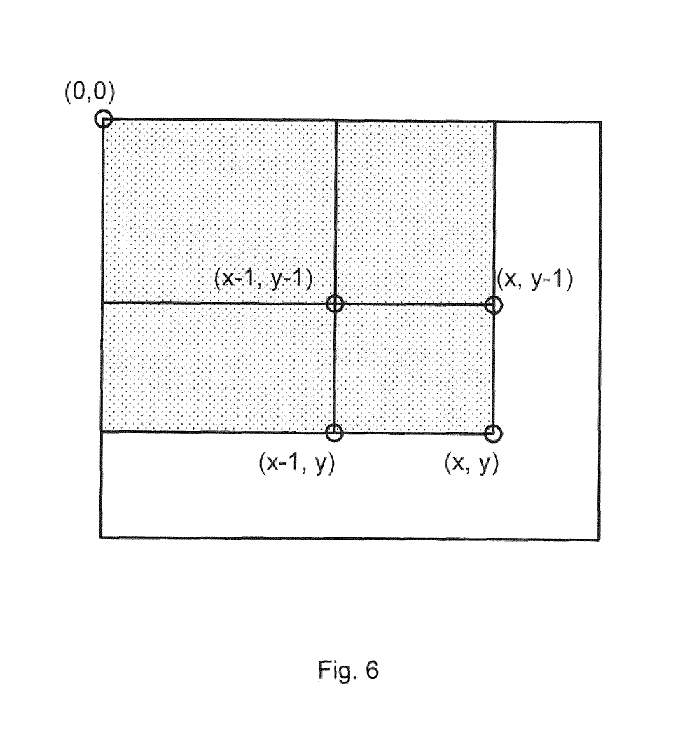

FIG. 6 schematically depicts an example of how the method of calculating an accumulation value at a pixel operates. As shown in FIG. 6, each circle represents a coordinate of a pixel in the image. According to equation (5), the accumulation value at the pixel (x,y), A(x,y), may be defined as the summation of all the pixel values in the rectangular area (as shaded in FIG. 6) one diagonal of which starts at pixel (0,0) and ends at pixel (x,y). As shown, the pixel (x,y) has at least three neighboring pixels, including the pixel (x−1,y−1), the pixel (x,y−1), and the pixel (x−1,y). Accordingly, the accumulation value at pixel (x−1, y−1), namely A(x−1, y−1), may be defined as the summation of all the pixel values in the rectangular area one diagonal of which starts at pixel (0,0) and ends at pixel (x−1, y−1). The accumulation value at the pixel (x, y−1), namely A(x, y−1), may be defined as the summation of all the pixel values in the rectangular area one diagonal of which starts at pixel (0,0) and ends at pixel (x, y−1). And, the accumulation value at the pixel (x−1, y), namely A(x−1, y), may be defined as the summation of all the pixel values in the rectangular area one diagonal of which starts at pixel (0,0) and ends at pixel (x−1, y). Thus, the accumulation value at pixel (x,y), i.e., A(x,y) may be expressed by the summation of the accumulation values at the surrounding pixels. Specifically,

A(x,y)=S(x,y)+A(x,y−1)+A(x−1,y)−A(x−1,y−1) (6)

Now, an integration value between pixel (x₁,y₁) and pixel (x₂,y₂) of an image of the object may be defined as:

I(x₁,y₁,x₂,y₂)=Σ_{x′=x}_{₁}^{x}^{₂}Σ_{y′=y}_{₁}^{y}^{₂}S(x′,y′) (7)

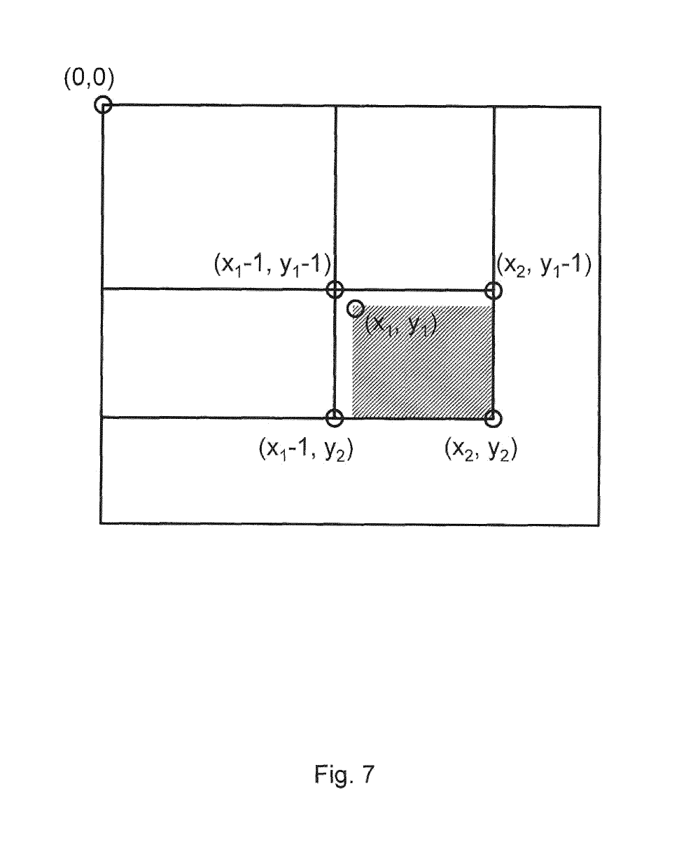

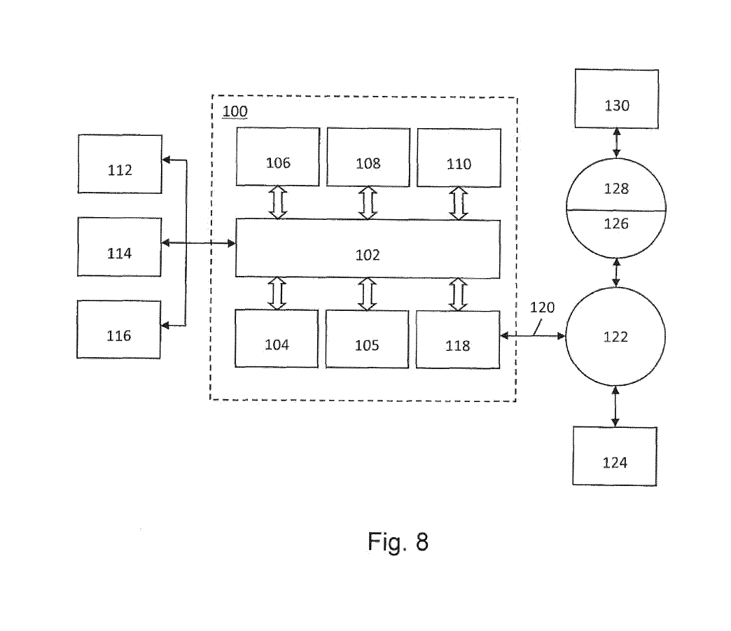

FIG. 7 schematically depicts an example of how the method of calculating an integration value between two pixels works. As shown in FIG. 7, each circle represents a coordinate of pixel of the image of the object. According to equation (7), the integration value between pixel (x₁,y₁) and pixel (x₂,y₂), i.e., I(x₁,y₁,x₂,y₂) is defined as summation of all pixel values in the rectangular area (as shaded in FIG. 7) of which one diagonal starts at the pixel (x₁,y₁) and ends at the pixel (x₂, y₂). Further, I(x₁,y₁,x₂,y₂) may be expressed by the combination of accumulation values at the surrounding pixels to the shaded rectangular area, including e.g., the pixel (x₁−1,y₁−1), the pixel (x₂,y₁−1), and the pixel (x₁−1,y₂). Specifically, the integration value I(x₁,y₁,x₂,y₂) may be expressed by:

I(x₁,y₁,x₂,y₂)=A(x₂,y₂)+A(x₁−1,y₁−1)−A(x₁−1,y₂)−A(x₂,y₁−1) (8)

By incorporating the integration value I(x₁,y₁,x₂,y₂) into equation (4), equation (4) becomes:

$$D ( x , y ) = ( {k}_{v} - {k}_{w} ) I ( x - ⌊ \frac{{k}_{c}}{2} ⌋ , y - ⌊ \frac{{k}_{c}}{2} ⌋ , x + ⌊ \frac{{k}_{c}}{2} ⌋ , y + ⌊ \frac{{k}_{c}}{2} ⌋ ) + {k}_{w} I ( x - ⌊ \frac{k}{2} ⌋ , y - ⌊ \frac{k}{2} ⌋ , x + ⌊ \frac{k}{2} ⌋ , y + ⌊ \frac{k}{2} ⌋ ) \qquad ( 9 )$$

And, by further incorporating equation (8) into equation (9), equation (9) becomes:

$$D ( x , y ) = ( {k}_{v} - {k}_{w} ) \{ A ( x + ⌊ \frac{{k}_{c}}{2} ⌋ , y + ⌊ \frac{{k}_{c}}{2} ⌋ ) + A ( x - ⌊ \frac{{k}_{c}}{2} ⌋ - 1 , y - ⌊ \frac{{k}_{c}}{2} ⌋ - 1 ) - A ( x - ⌊ \frac{{k}_{c}}{2} ⌋ - 1 , y + ⌊ \frac{{k}_{c}}{2} ⌋ ) - A ( x + ⌊ \frac{{k}_{c}}{2} ⌋ , y - ⌊ \frac{{k}_{c}}{2} ⌋ - 1 ) \} + {k}_{w} \{ A ( x + ⌊ \frac{k}{2} ⌋ , y + ⌊ \frac{k}{2} ⌋ ) + A ( x - ⌊ \frac{k}{2} ⌋ - 1 , y - ⌊ \frac{k}{2} ⌋ - 1 ) - A ( x - ⌊ \frac{k}{2} ⌋ - 1 , y + ⌊ \frac{k}{2} ⌋ ) - A ( x + ⌊ \frac{k}{2} ⌋ , y - ⌊ \frac{k}{2} ⌋ - 1 ) \} \qquad ( 10 )$$

As seen from equation (10), the calculation of the convolution of every output pixel of the image D may be calculated using 8 additions and 2 multiplications (or effectively just 1 multiplication if the value of k_{w} is 1 or −1). In particular, every output pixel of the image D is a weighted combination of accumulative values from surrounding pixels, where the weighting is based on the base and center values of the pixels of the kernel. These calculations would be repeated M×N times for each of the pixels of the input image. The amount of computation for each pixel of the image D is constant regardless of the size of the high-pass filter kernel K. With such a process, the time to determine a convolution of an image with a kernel is significantly reduced.

Additionally, at any point of the convolution calculation, only the accumulation values associated with (k+1) rows of pixels of the image of the object are needed to implement the algorithm according to equation (10). Comparing with other solutions in which each pixel of the image D is calculated based on all the pixel values of the image of the object, the processing needed to implement the algorithm according to equation (10) is greatly reduced. Thus, this property can be used to optimize memory usage by the algorithm without significantly sacrificing performance. That is, the accumulative image is calculated in the same loop as the convolution output, so instead of allocating the memory space with a full accumulation image of size M×N, a much smaller (k+1)×N image is used. As the convolution proceeds the row of accumulative images that is no longer needed is overwritten with a latest calculation. In other words, the values that around a current pixel under consideration are stored in memory for use with adjacent pixels when under consideration. But, when the subsequent pixels under consideration no longer require one of the stored values, that stored value can be overwritten and thus saving memory usage.

An example pseudo code for implementing the algorithm is shown in Table 1 below:

TABLE 1
Pseudo-code to implement detection of a defect of an object

Input:
Source Image: S[M, N]
Kernel Size: K
Kernel Base Value: Kw
Kernel Center Size: Kc
Kernel Center Value: Kv
Output:
Destination Image: D[M, N]
Process:
1. Allocate the accumulative image A[K+1, N] with a number of rows equal to (K+1), and a
number of columns the same as the source image (N). Set the initial value of every pixel in the
accumulative image to 0.
2. Repeat for every pixel in the source image S(y, x), the following calculation:
a. Calculate the row index mapping from source image (y) to the accumulative image. This is for
memory space optimization.
accum_y = y mod (K+1)
accum_y_1 = (y−1) mod (K+1)
b. Incrementally calculate the accumulative image value A(accum_y, x) using the neighboring
accumulative image value and the source image value:
A(accum_y, x) = S(y, x) + A(accum_y, x−1) + A(accum_y_1, x) − A (accum_y_1, x−1)
c. IF y > K and x > K, calculate the destination image pixel value with the following method:
i) Calculate the center row and column index
y_center = y − └k/2┘
x_center = x − └k/2┘
ii) Calculate the row and column indexes for the four corners that are involved in the
convolution:
y_left_top = y − k −1
x_left_top = x − k −1
y_right_bottom = y
x_right_bottom = x
y_center_left_top = y − └(k + kc)/2┘ −1
x_center_left_top = x − └(k + kc)/2┘ −1
y_center_right_bottom = y − └(k − kc)/2┘
x_center_right_bottom = x − └(k − kc)/2┘
iii) Calculate the row index in the accumulative image for the four involved corner points:
y_acc_left_top = y_left_top mod (K+1)
y_acc_right_bottom = y_right_bottom mod (K+1)
y_acc_center_left_top = y_center_left_top mod (K+1)
y_acc_center_right_bottom = y_center_right_bottom mod (K+1)
iv) Calculate the convolution output at D(y_center, x_center) using the method provided in
equation (10)
D(y_center, x_center) = (Kv−Kw) { A(x_center_left_top, y_acc_center_left_top)
+A(x_center_right_bottom, y_acc_center_right_bottom)
−A(x_center_right_bottom, y_acc_center_left_top)
−A(x_center_left_top, y_acc_center_right_bottom) }
+(Kw) { A(x_left_top, y_acc_left_top)
+A(x_right_bottom, y_acc_right_bottom)
−A(x_right_bottom, y_acc_left_top)
−A(x_left_top, y_acc_right_bottom) }

In an embodiment, there is provided a method comprising: obtaining a first image of an object; generating a second image by convolving the first image with a filter kernel, wherein each pixel value of the second image is a weighted combination of a plurality of accumulation values associated with surrounding pixels of the first image; and determining, based on the second image, whether the object includes a defect.

In an embodiment, an accumulation value at a pixel of the first image is a combination of all the pixel values in an area of which a diagonal starts at the pixel at the origin of the first image and ends at the pixel of the first image. In an embodiment, the filter kernel is a high pass filter kernel. In an embodiment, the filter kernel comprises a sub-matrix in the center, each element in the sub-matrix having a first value, and each element outside of the sub-matrix having a second value, and wherein the first value is greater than the second value. In an embodiment, the weighting is based on the first and second values. In an embodiment, the combination comprises a combination of eight accumulation values, each associated with a different pixel of the surrounding pixels. In an embodiment, the pixel value D(x,y) of the second image is determined by:

$$D ( x , y ) = ( {k}_{v} - {k}_{w} ) \{ A ( x + ⌊ \frac{{k}_{c}}{2} ⌋ , y + ⌊ \frac{{k}_{c}}{2} ⌋ ) + A ( x - ⌊ \frac{{k}_{c}}{2} ⌋ - 1 , y - ⌊ \frac{{k}_{c}}{2} ⌋ - 1 ) - A ( x - ⌊ \frac{{k}_{c}}{2} ⌋ - 1 , y + ⌊ \frac{{k}_{c}}{2} ⌋ ) - A ( x + ⌊ \frac{{k}_{c}}{2} ⌋ , y - ⌊ \frac{{k}_{c}}{2} ⌋ - 1 ) \} + {k}_{w} \{ A ( x + ⌊ \frac{k}{2} ⌋ , y + ⌊ \frac{k}{2} ⌋ ) + A ( x - ⌊ \frac{k}{2} ⌋ - 1 , y - ⌊ \frac{k}{2} ⌋ - 1 ) - A ( x - ⌊ \frac{k}{2} ⌋ - 1 , y + ⌊ \frac{k}{2} ⌋ ) - A ( x + ⌊ \frac{k}{2} ⌋ , y - ⌊ \frac{k}{2} ⌋ - 1 ) \}$$

wherein the filter kernel matrix has a size k with a sub-matrix of size k_{c}, wherein the pixels of the filter kernel matrix have a base value k_{w} and the pixels of the sub-matrix have a base value kᵥ, and wherein A(i,j) is the summation of pixel values of the first image to the point i,j. In an embodiment, determining, based on the second image, whether the object includes a defect comprises determining that the second image comprises a high spatial frequency component, the defect corresponding to the high spatial frequency component. In an embodiment, the defect comprises a particle on the object. In an embodiment, the first image of the object comprises a combination of an image of the object before a patterning process and an image of the object after the patterning process. In an embodiment, the combination comprises a difference between the image of the object before the patterning process and the image of the object after the patterning process. In an embodiment, the object comprises a patterning device.

In an embodiment, there is provided a non-transitory computer program product comprising machine-readable instructions configured to cause a processor to cause performance of a method as described herein.

In an embodiment, there is provided a system comprising: a patterning device inspection tool configured to provide an image of a patterning device; and an image analysis engine comprising a non-transitory computer program product as described herein. In an embodiment, the system further comprises a lithographic apparatus comprising a support structure configured to hold the patterning device to modulate a radiation beam.

Referring to FIG. 8, a computer system 100 is shown. The computer system 100 includes a bus 102 or other communication mechanism to communicate information, and a processor 104 (or multiple processors 104 and 105) coupled with bus 102 to process information. In an embodiment, computer system 100 includes a main memory 106, such as a random access memory (RAM) or other dynamic storage device, coupled to bus 102 to store information and instructions to be executed by processor 104. Main memory 106 may be used to store temporary variables or other intermediate information during execution of instructions to be executed by processor 104. In an embodiment, computer system 100 includes a read only memory (ROM) 108 or other static storage device coupled to bus 102 to store essentially static information and instructions for processor 104. In an embodiment, a storage device 110, such as a solid state drive, magnetic disk or optical disk, is provided and coupled to bus 102 to store information and instructions.

Computer system 100 may be coupled via bus 102 to a display 112, such as a cathode ray tube (CRT) or flat panel or touch panel display, to display information to a computer user. In an embodiment, an input device 114, including or providing alphanumeric and other keys, is coupled to bus 102 to communicate information and command selections to processor 104. Another type of user input device is cursor control 116, such as a mouse, a trackball, or cursor direction keys, to communicate direction information and command selections to processor 104 and to control cursor movement on display 112. A touch panel (screen) display may also be used as an input device.

The computer system 100 may be suitable to implement methods as described herein in response to processor 104 executing one or more sequences of one or more instructions contained in, e.g., main memory 106. Such instructions may be read into main memory 106 from another computer-readable medium, such as storage device 110. In an embodiment, execution of sequences of instructions contained in main memory 106 causes processor 104 to perform process steps described herein. One or more processors in a multi-processing arrangement may be employed to execute the sequences of instructions contained in main memory 106. In an embodiments, hard-wired circuitry may be used in place of or in combination with software instructions. Thus, embodiments are not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, solid state, optical or magnetic disks, such as storage device 110. Volatile media include dynamic memory, such as main memory 106. Non-volatile and volatile media are considered non-transitory. Non-transitory transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, a solid state disk or any other memory chip or cartridge, a carrier wave as described herein, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over communications medium (e.g., by line or wireless). Computer system 100 can receive the transmitted data and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, commonly referred to as the internet 128. Local network 122 and internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the internet example, a server 130 might transmit a requested code for an application program through internet 128, ISP 126, local network 122 and communication interface 118. In accordance with one or more embodiments, one such downloaded application implements a method as described herein. The received code may be executed by processor 104 as it is received, and/or stored in storage device 110, or other non-volatile storage for later execution. In this manner, computer system 100 may obtain application code.

The term “optimizing” and “optimization” as used herein mean adjusting an apparatus or process, e.g., a lithographic apparatus or an optical lithography process step, such that patterning and/or device fabrication results and/or processes (e.g., of lithography) have one or more desirable characteristics, such as higher accuracy of projection of a design layout on a substrate, larger process window, etc.

An embodiment may take the form of a computer program containing one or more sequences of machine-readable instructions describing a method as disclosed herein, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

Any controllers described herein may each or in combination be operable when the one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include data storage medium for storing such computer programs, and/or hardware to receive such medium. So the controller(s) may operate according the machine readable instructions of one or more computer programs.

Although specific reference may have been made above to the use of embodiments in the context of optical lithography, it will be appreciated that an embodiment may be used in other applications, for example imprint lithography, and where the context allows, is not limited to optical lithography. In imprint lithography, a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

Further, although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after pattern transfer, in for example a track (a tool that typically applies a layer of resist to a substrate and develops the patterned resist), an inspection tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The descriptions above are intended to be illustrative, not limiting. Thus, it will be apparent to one skilled in the art that modifications may be made to the invention as described without departing from the scope of the claims set out below. For example, one or more aspects of one or more embodiments may be combined with or substituted for one or more aspects of one or more other embodiments as appropriate. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance. The breadth and scope of the invention should not be limited by any of the above-described exemplary embodiments, but should be defined only in accordance with the following claims and their equivalents.

1. A method comprising:
obtaining a first image of an object;
generating, by hardware computer system, a second image by convolving the first image with a filter kernel, wherein each pixel value of the second image is a weighted combination of a plurality of accumulation values associated with surrounding pixels of the first image; and
determining, based on the second image, whether the object includes a defect.

2. The method of claim 1, wherein an accumulation value at a pixel of the first image is a combination of all the pixel values in an area of which a diagonal starts at the pixel at the origin of the first image and ends at the pixel of the first image.

3. The method of claim 1, wherein the filter kernel is a high pass filter kernel.

4. The method of claim 3, wherein the filter kernel comprises a sub-matrix in the center, each element in the sub-matrix having a first value, and each element outside of the sub-matrix having a second value, and wherein the first value is greater than the second value.

5. The method of claim 4, wherein the weighting is based on the first and second values.

6. The method of claim 1, wherein the weighted combination comprises a combination of eight accumulation values, each associated with a different pixel of the surrounding pixels.

7. The method of claim 1, wherein the pixel value D(x,y) of the second image is determined by:
$$D ( x , y ) = ( {k}_{v} - {k}_{w} ) \{ A ( x + ⌊ \frac{{k}_{c}}{2} ⌋ , y + ⌊ \frac{{k}_{c}}{2} ⌋ ) + A ( x - ⌊ \frac{{k}_{c}}{2} ⌋ - 1 , y - ⌊ \frac{{k}_{c}}{2} ⌋ - 1 ) - A ( x - ⌊ \frac{{k}_{c}}{2} ⌋ - 1 , y + ⌊ \frac{{k}_{c}}{2} ⌋ ) - A ( x + ⌊ \frac{{k}_{c}}{2} ⌋ , y - ⌊ \frac{{k}_{c}}{2} ⌋ - 1 ) \} + {k}_{w} \{ A ( x + ⌊ \frac{k}{2} ⌋ , y + ⌊ \frac{k}{2} ⌋ ) + A ( x - ⌊ \frac{k}{2} ⌋ - 1 , y - ⌊ \frac{k}{2} ⌋ - 1 ) - A ( x - ⌊ \frac{k}{2} ⌋ - 1 , y + ⌊ \frac{k}{2} ⌋ ) - A ( x + ⌊ \frac{k}{2} ⌋ , y - ⌊ \frac{k}{2} ⌋ - 1 ) \}$$
wherein the filter kernel matrix has a size k with a sub-matrix of size k_{c}, wherein the pixels of the filter kernel matrix have a base value k_{w} and the pixels of the sub-matrix have a base value kᵥ, and wherein A(i,j) is the summation of pixel values of the first image to the point i,j.

8. The method of claim 1, wherein determining, based on the second image, whether the object includes a defect comprises determining that the second image comprises a high spatial frequency component, the defect corresponding to the high spatial frequency component.

9. The method of claim 1, wherein the defect comprises a particle on the object.

10. The method of claim 1, wherein the first image of the object comprises a combination of an image of the object before a patterning process and an image of the object after the patterning process.

11. The method of claim 10, wherein the combination comprises a difference between the image of the object before the patterning process and the image of the object after the patterning process.

12. The method of claim 1, wherein the object comprises a patterning device.

13. A non-transitory computer program product comprising machine-readable instructions that, when executed, are configured to cause a processor system to at least:
obtain a first image of an object;
generate a second image by convolving the first image with a filter kernel, wherein each pixel value of the second image is a weighted combination of a plurality of accumulation values associated with surrounding pixels of the first image; and
determine, based on the second image, whether the object includes a defect.

14. A system comprising:
a patterning device inspection tool configured to provide an image of a patterning device;
an image analysis engine comprising the non-transitory computer program product of claim 13.

15. (canceled)

16. The computer program product of claim 13, wherein an accumulation value at a pixel of the first image is a combination of all the pixel values in an area of which a diagonal starts at the pixel at the origin of the first image and ends at the pixel of the first image.

17. The computer program product of claim 13, wherein the filter kernel is a high pass filter kernel.

18. The computer program product of claim 13, wherein the filter kernel comprises a sub-matrix in the center, each element in the sub-matrix having a first value, and each element outside of the sub-matrix having a second value, and wherein the first value is greater than the second value.

19. The computer program product of claim 13, wherein the weighted combination comprises a combination of eight accumulation values, each associated with a different pixel of the surrounding pixels.

20. The computer program product of claim 13, wherein the instructions configured to determine, based on the second image, whether the object includes a defect comprises instructions configured to determine that the second image comprises a high spatial frequency component, the defect corresponding to the high spatial frequency component.

21. The computer program product of claim 13, wherein the pixel value D(x,y) of the second image is determined by:
$$D ( x , y ) = ( {k}_{v} - {k}_{w} ) \{ A ( x + ⌊ \frac{{k}_{c}}{2} ⌋ , y + ⌊ \frac{{k}_{c}}{2} ⌋ ) + A ( x - ⌊ \frac{{k}_{c}}{2} ⌋ - 1 , y - ⌊ \frac{{k}_{c}}{2} ⌋ - 1 ) - A ( x - ⌊ \frac{{k}_{c}}{2} ⌋ - 1 , y + ⌊ \frac{{k}_{c}}{2} ⌋ ) - A ( x + ⌊ \frac{{k}_{c}}{2} ⌋ , y - ⌊ \frac{{k}_{c}}{2} ⌋ - 1 ) \} + {k}_{w} \{ A ( x + ⌊ \frac{k}{2} ⌋ , y + ⌊ \frac{k}{2} ⌋ ) + A ( x - ⌊ \frac{k}{2} ⌋ - 1 , y - ⌊ \frac{k}{2} ⌋ - 1 ) - A ( x - ⌊ \frac{k}{2} ⌋ - 1 , y + ⌊ \frac{k}{2} ⌋ ) - A ( x + ⌊ \frac{k}{2} ⌋ , y - ⌊ \frac{k}{2} ⌋ - 1 ) \}$$
wherein the filter kernel matrix has a size k with a sub-matrix of size k_{c}, wherein the pixels of the filter kernel matrix have a base value k_{w} and the pixels of the sub-matrix have a base value kᵥ, and wherein A(i,j) is the summation of pixel values of the first image to the point i,j.

22. The computer program product of claim 13, wherein the first image of the object comprises a combination of an image of the object before a patterning process and an image of the object after the patterning process.
